(19) United States
(12) Patent Application Publication
(10) Pub. No.: US 2007/0246820 A1
(43) Pub. Date: Oct. 25, 2007

(54) Die protection process

(75) Inventors: Wael Zohni, San Jose, CA (US); Salvador A. Tostado, Los Gatos, CA (US); David R. Baker, Cupertino, CA (US)

Correspondence Address: TESSERA;LERNER DAVID et al., 600 SOUTH AVENUE WEST, WESTFIELD, NJ, 07090, US

(73) Assignee: Tessera, Inc.

(21) Appl. No.: 11/406,666

(22) Filed: Apr. 19, 2006

(51) Int. Cl. H01L 23/12; H01L 21/56; H01L 23/28

(52) U.S. Cl. 257/701; 438/114; 438/126; 257/787; 257/778

(57) ABSTRACT

A method of protecting a microelectronic chip contained in a microelectronic assembly, including the steps of depositing a protective coating across the exposed faces of the chip. The coating, having a low modulus of elasticity, is applied across the chip so as to reduce the overall height of the assembly while still protecting the exposed face and corners of the chip from damage.

### BACKGROUND

The present invention relates to the art of electronic packaging, and more specifically to a method of protecting a surface of a microelectronic element, such as a semiconductor chip.

Modern electronic devices utilize semiconductor chips, commonly referred to as “integrated circuits” which incorporate numerous electronic elements. Chips are almost universally formed by processing a large semiconductor wafer to form numerous regions, each including the microscopic circuitry of a single chip, and then cutting or “dicing” the wafer to form numerous separate chips. Each chip includes a flat, typically rectangular body having front and back surfaces, with contacts on the front surface connected to the microscopic circuitry within the chip. These chips are then mounted on substrates, known alternatively as interconnect elements or package elements, which physically support the chips and electrically interconnect each chip with other elements of the circuit. The substrate may be a part of a discrete chip package used to hold a single chip and equipped with terminals for interconnection to external circuit elements.

Once a chip has been mounted to the substrate, the back side and edges of the chip remain exposed to damage that can occur from further handling. Specifically, chipping and cracking along the edges and corners of the unprotected chip can occur. Such damage can in turn prevent proper operation of the chip.

Conventional means for protecting the chip from such damage typically include surrounding the chip with an overmold. Typically, the overmold is made of a hard material and is attached to the substrate in a way that prevents contact with the chip. In this way, the chip package can withstand the forces prevalent during handling without damaging the chip. The overmold is limiting however, in that it creates extra height to the chip package. This is especially limiting when the chip packages are in a “stacked” configuration.

In order to decrease the area occupied by chip packages, a number of chips or other microelectronic elements, each mounted to a package element, are vertically stacked one on top of another and interconnected to form a stacked package. This stacked configuration adds to the height of the circuit. However, in many applications low height is essential, as for example, in assemblies intended for use in miniaturized cellular telephones and other devices to be worn or carried by the user. To decrease the height of the stacked packages, it is preferable to reduce the vertical pitch of the packaged chips. In such circumstances, the overmold can act as a lower limit for the spacing between these elements.

### SUMMARY

In particular embodiments, the height of the chip above the package element is reduced while still protecting the exposed face and corners of the chip from damage.

In one embodiment of the present invention, a microelectronic chip has a front face and a back face opposite the front face. The thickness of the microelectronic chip is less than approximately 400 micrometers (μm). A package element is mounted to the front face of the chip, while a thin protective coating including a low modulus material, overlies the back face of the chip.

In one embodiment of the present invention, the microelectronic chip has a plurality of edges extending between the front and back faces and a plurality of corners between these edges. The protective coating overlies at least one of the edges or corners.

In another embodiment of the present invention, a plurality of microelectronic assemblies are vertically stacked to form a stacked microelectronic assembly. A thin protective coating overlying at least one chip in the stacked assemblies.

One method of the present invention includes applying a protective coating to the back face of the microelectronic element, wherein the coating is a flowable material and is applied through a process of stencil printing.

Another method of the present invention includes a process wherein the coating is in the form of a flexible tape material having a self-adhesive property and is applied to individual chips by a roll lamination process. Alternatively, this process may be applied simultaneously to a plurality of chips attached to each other in the form of a microelectronic wafer or portion thereof. Subsequently, the coated wafer is diced into the microelectronic chips.

Yet another method of the present invention includes applying the coating material to the back face of the microelectronic element through a process of screen printing.

### BRIEF DESCRIPTION OF THE DRAWINGS

FIG. 1 is a cross sectional view of a microelectronic assembly having a protective coating in accordance with an embodiment of the invention.

FIG. 2 is a plan view of the microelectronic assembly of FIG. 1, looking towards a front face of a chip.

FIG. 3 is a perspective view of stacked microelectronic assemblies, in accordance with an embodiment of the invention.

FIG. 4 is an exploded view of a protective coating being applied by a stencil printing device.

FIG. 5 is a cross-sectional view of the device of FIG. 4.

FIG. 6 is a cross-sectional view of a protective coating being applied by a screen printing method.

FIG. 7 is a cross-sectional view of a protective coating being applied by a dispensing method.

FIG. 8 is a top plan view of a wafer.

FIG. 9 is a cross-sectional view of a microelectronic wafer having a protective coating in accordance with an embodiment of the invention.

FIG. 10 is a cross-sectional view of a prior art microelectronic assembly having an overmold.

### DETAILED DESCRIPTION

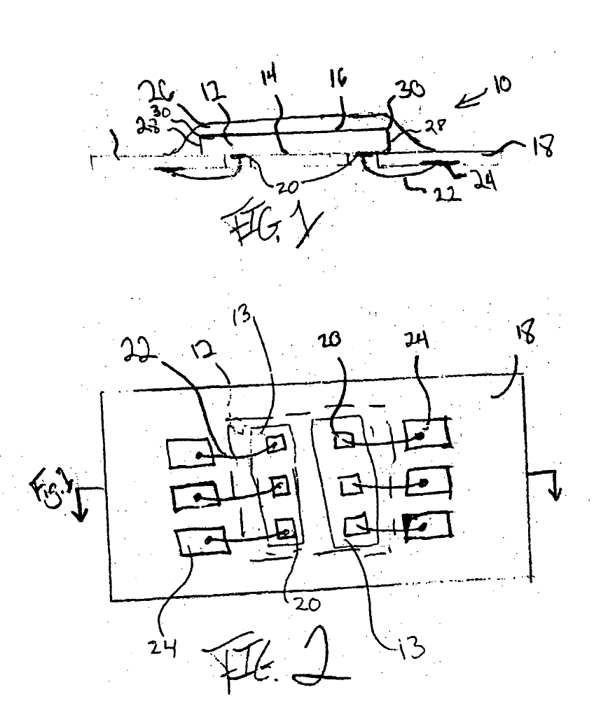

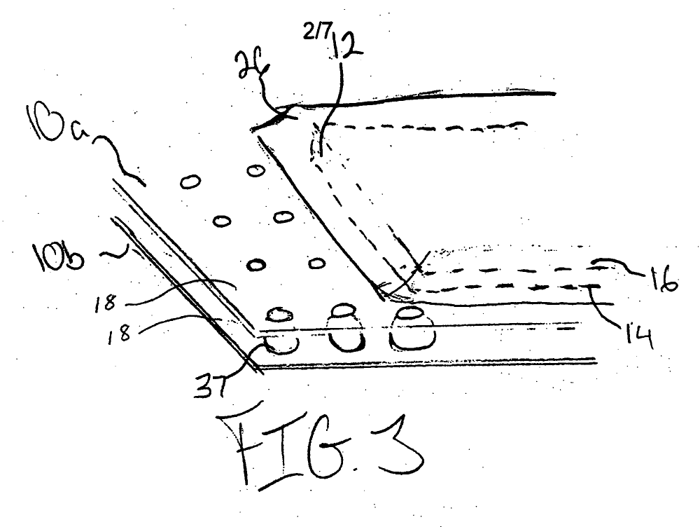

FIG. 1 and FIG. 2 show a diagrammatic sectional view of a microelectronic assembly with a protective coating according to one embodiment of the invention. The microelectronic assembly 10 includes a chip 12 having a front face 14 and a back face 16, with the front face 14 being mounted to a substrate 18. The substrate includes slots 13 or other openings aligned with bond pads 20 exposed at the front face 14 of the chip. The bond pads 20 are electrically connected by conductive leads 22 to contacts 24 contained on the substrate 14. The substrate 18 incorporates a dielectric body which desirably is as thin as is practicable. For example, the substrate may include one or more layers of dielectric such as, without limitation, polymide, glass, ceramic or undoped semiconductor.

A thin protective coating 26 overlies the back face 16 of the chip 12. The coating 26 is made of a low modulus material having an elastic modulus of less than approximately 10 Gigapascal (GPa). In one embodiment, the low modulus coating is made of polymers or elastomers, such as polymides, bismaleimide matrix adhesives, epoxy matrix adhesives, or silicone elastomers. The thickness of the coating 26, which is displayed as the vertical dimension in FIG. 1, is approximately 25 μm to 150 μm, in order to provide sufficient protection of the chip 12 under most circumstances. In addition, the chip 12 has a thickness between its front face and back face that is less than approximately 400 μm.

For the embodiment shown in FIG. 1, a microelectronic assembly 10 includes a protective coating 26 overlying the plurality of edges 28 extending between the front face 12 and the back face 16 of the chip 12. The protective coating 26 may also overlie the corners 30 running between the plurality of edges 28 and back face 16. This coating 26 over the plurality of chip edges 28 and corners 30 further protects against potential crack propagation that could occur during shipping and handling.

The thickness of the protective coating 26 at the edges 28 and corners 30 need not be uniform and need not be the same as the thickness across the back face 16 of the chip 12. For example, a protective coating 26 having a thickness of approximately 44 μm across the back face 16 of the chip 12 may have a thickness of approximately 20 μm at a corner 30 and approximately 70 μm at an edge 28.

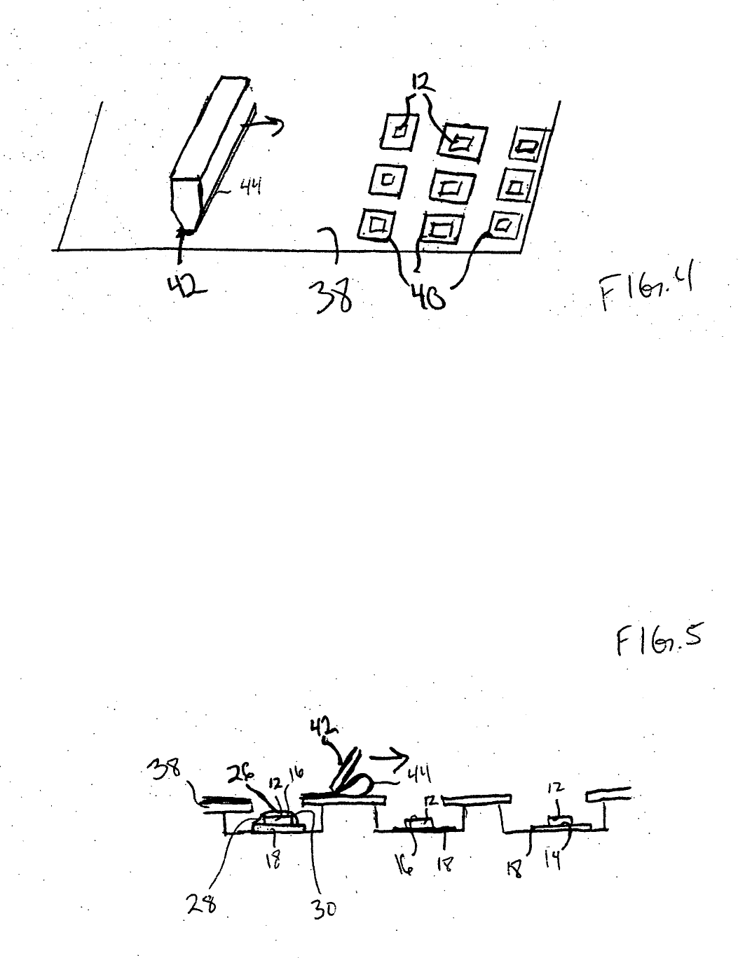

For the embodiment shown in FIG. 3, a protective coating 26 is provided on at least one of a plurality of microelectronic assemblies 10 which are mounted together in a stacked configuration. In this embodiment, the substrate 18 of at least one microelectronic assembly 10a is mounted to overlie another microelectronic assembly 10b. The substrates 18 of the two microelectronic assemblies are mounted and conductively connected to each other with a connecting material such as solder balls 37. In addition, at least one of the microelectronic assemblies 10 has a protective coating 26 overlying the back face 16 of a chip 12.

The vertically stacked microelectronic assemblies allow for a greater number of microelectronic elements to be placed in a given area. To further decrease the space these microelectronic assemblies occupy, the vertical height or thickness of each assembly in the stack can be reduced by using a thinner chip 12. However, as the thickness of the chip 12 is reduced, the risk of damage to the chip, such as by cracking and chipping during handling, increases. This embodiment therefore provides for a coating 26, which will protect the chip 12 without greatly increasing the thickness of the complete microelectronic assembly.

The thickness of each microelectronic assembly is determined by the overall height or vertical dimension of the substrate 18, the chip 12, and the protective coating 26 of the complete assembly. The use of a protective coating as embodied in the present invention allows a thinner chip 12 to be used without increasing the risk of damage to cracking or chipping.

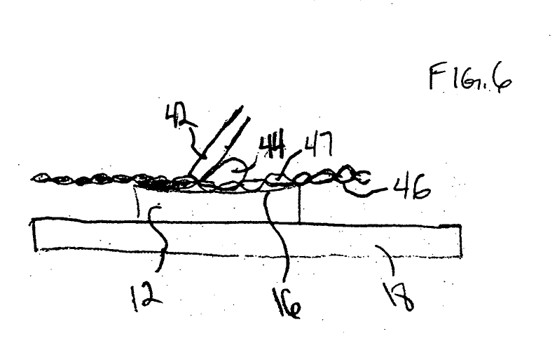

In one embodiment, the protective coating 26 is applied through a process of stencil printing, as shown in FIG. 4 and FIG. 5. As shown in FIG. 4, a stencil mask 38 having a plurality of apertures 40 each large enough to expose a back face of one chip is aligned with a plurality of chips 12. In this embodiment, a front face 14 of each chip 12 is mounted to a substrate 18, as shown in FIG. 5. A stencil mask 38, preferably including a laser-formed, stainless steel material, is used. The distance between the stencil and the back face of the chip is preferably between about 5 and 15 mils. A squeegee blade 42 then passes over the stencil mask 38 at a uniform velocity while distributing the protective coating material in the form of a paste 44. The stencil mask 38 is then removed leaving a completed microelectronic element including a chip 12, substrate 18 and protective coating 26 overlying the back face 16, edges 28 and corners 30 of the chip.

The thickness of the protective coating 26 in the completed microelectronic assembly is affected by the downward force exerted by the squeegee blade 42 as the squeegee blade 42 passes over the stencil mask 38. For instance, the coating 26 becomes thinner as the downward force exerted by the squeegee blade 42 is increased.

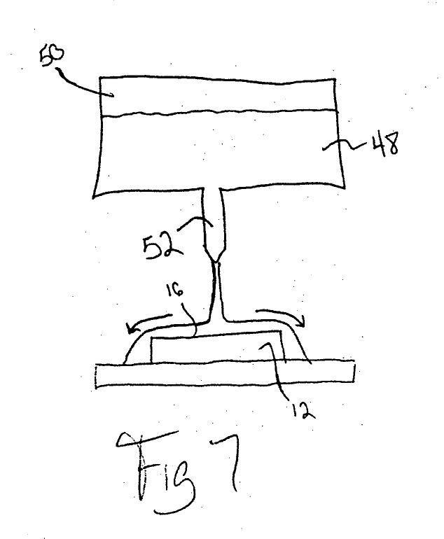

In another embodiment, the protective coating 26 is applied through a process of screen printing, as shown in FIG. 6. In this process, a printing mesh 46, typically including strands of stainless steel or a similar material, is placed over the back face 16 of a chip 12. This process is typically performed simultaneously to a plurality of chips arranged in an array. For ease of reference, only a single chip is illustrated. A squeegee blade 42 then passes over the printing mesh 46 at a uniform velocity while distributing the protective coating material in the form of a paste 44. The strands of the mesh 46 provide a plurality of small apertures 47, through which the coating is forced onto the back face 16 by the squeegee to form a protective coating overlying the back face.

In yet another embodiment (FIG. 7), the protective coating is applied to the microelectronic assembly by a dispensing process. In this process, the coating material 48 is stored in a cartridge 50 and is dispensed onto the back face 16 of the chip 12 through a nozzle 52. The coating material 48 may be forced through the nozzle by means of a pump or other mechanical device. The flow rate of the coating material 48 through the nozzle must be minimized as to assure an even distribution. Therefore, the opening of the nozzle 52 should be small enough to assure a low flow rate and even distribution.

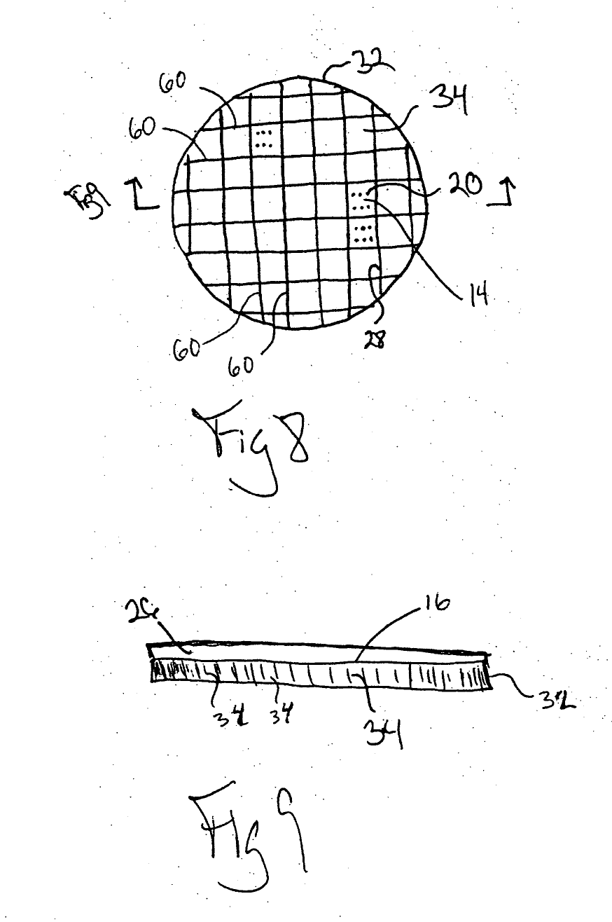

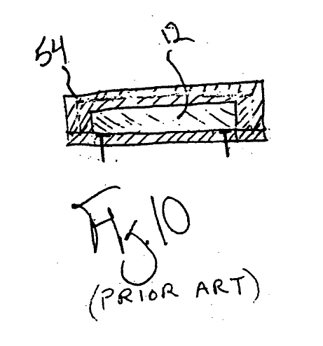

In an alternative embodiment, a protective coating 26 is applied to a chip while it remains attached to other chips in form of a wafer 32, as shown in FIG. 8 and FIG. 9. The wafer 32 includes a plurality of individual chips 34, attached to each other at dicing lines 60, each such clip containing internal electronic circuitry (not shown) and bond pads 20 on a front face, as previously described above with reference to 14. Only a few of the bond pads 20 are depicted for clarity of illustration in FIG. 9. A protective coating 26 is applied across the back face 16 of the wafer 32. The wafer 32 is then severed into individual chips 34 by conventional processes such as sawing, etching or scribing and breaking the material of the wafer along the dicing lanes 60.

The protective coating 26 may be applied to the wafer in various methods. For example, the coating 26 may consist of a pre-formed tape material which can be applied by a roll lamination process, or the protective coating 26 may be applied through a spin-coating method.

The structures and methods discussed above provide a compact microelectronic assembly, while protecting a microelectronic element such as a chip from damage due to stresses common in subsequent manufacturing processes and/or shipping and handling. The current industry practice of applying an overmold 54 is illustrated in FIG. 10. However, the cost of applying such an overmold is more expensive than the embodiments described herein. Moreover, the costs associated with the tooling needed to size and form an overmold 54 to the dimensions of a given microelectronic assembly may also be avoided through use of the structures and processes described herein. The application of the overmold can also introduce various stresses onto the chip 12 which can itself increase the risk of damage. A low modulus coating applied to chips or microelectronic assemblies as discussed herein protects against these stresses.

As these and other variations and combinations of the features discussed above can be utilized without departing from the present invention as defined by the claims, the foregoing description of embodiments should be taken by way of illustration rather than by way of limitation of the invention as defined by the claims.

1. An assembly including a microelectronic element comprising:
(a) a microelectronic element having a front face and a back face opposite the front face;
(b) a package element mounted to the front face of the microelectronic element; and
(c) a coating overlying the back face of the microelectronic element, the coating having a low modulus of elasticity and a thickness less than 150 μm.

2. An assembly as claimed in claim 1, wherein the microelectronic element has a thickness less than 400 μm.

3. An assembly as claimed in claim 1, wherein the microelectronic element further includes a plurality of edges extending between the front and back faces and the coating overlies each of the plurality of edges and the back face.

4. An assembly as claimed in claim 1, wherein the coating has a largely uniform thickness across the back face of the microelectronic element.

5. An assembly as claimed in claim 3, wherein the microelectronic element further includes a plurality of corners between the plurality of edges and the back face, and the coating has a thickness of at least approximately 20 μm at each of the corners.

6. A method of protecting a microelectronic element comprising:
(a) providing a microelectronic element having a front face and a back face opposite the front face;
(b) mounting a package element to the front face of the microelectronic element; and
(c) covering the back face of the microelectronic element with a coating having a low modulus of elasticity and a thickness of less than 150 μm.

7. A method as claimed in claim 6, wherein the microelectronic element has a thickness less than 400 μm.

8. A method as claimed in claim 6, wherein the coating is formed by stenciling a flowable material over the back face of the microelectronic element.

9. A method as claimed in claim 6, wherein the coating is formed by adhering a flexible tape to the back face by a roll lamination process.

10. A method as claimed in claim 6, wherein the coating has a largely uniform thickness across the back face of the microelectronic element.

11. A method as claimed in claim 9, wherein the microelectronic element includes a wafer.

12. A method as claimed in claim 6, wherein the coating is formed by screen printing a flowable material over the back face of the microelectronic element.

13. A method as claimed in claim 6, wherein the microelectronic element includes a chip, the chip including bond pads exposed at the front face, and the package element includes contacts, and the method further includes conductively interconnecting the bond pads of the chip to the contacts of the package element after mounting the package element to the chip.

14. A method as claimed in claim 13, wherein the step of covering the back face of the microelectronic element with the coating is performed after said step of mounting the package element to the front face of the microelectronic element.

15. A method as claimed in claim 14, wherein the step of conductively interconnecting the bond pads of the chip to the contacts of the package element is performed after the step of covering the back face of the microelectronic element with the coating.

16. A method of protecting a microelectronic element comprising:
(a) providing a microelectronic wafer including a plurality of chips attached to each other at dicing lanes, the microelectronic wafer having a front face, a back face opposite the front face;
(b) covering the back face of the microelectronic element with a coating having a low modulus of elasticity and a thickness of less than 150 μm; and
(c) severing the microelectronic wafer along the dicing lanes into individual chips.

17. An method as claimed in claim 16, wherein the microelectronic wafer has a thickness less than 400 μm.

18. A method as claimed in claim 16, further comprising mounting a package element to the front face of at least one of the chips.

19. A method as claimed in claim 16, wherein the step of covering the back face of the microelectronic element with the coating includes spin-coating a flowable material onto said wafer.

20. A method as claimed in claim 16, wherein the step of providing the wafer includes grinding the wafer down from an initial thickness greater than 400 μm.

21. A method as claimed in claim 16, wherein the coating is formed by adhering a flexible tape to the back face by a roll lamination process.
